(19) United States
(12) Patent Application Publication
(10) Pub. No.: US 2012/0223780 A1
(43) Pub. Date: Sep. 6, 2012

(54) VOLTAGE CONTROLLED OSCILLATOR CIRCUIT

(75) Inventor: Go Urakawa, Kanagawa-ken (JP)

(73) Assignee: KABUSHIKI KAISHA TOSHIBA, Tokyo (JP)

(21) Appl. No.: 13/235,972

(22) Filed: Sep. 19, 2011

(30) Foreign Application Priority Data
Mar. 3, 2011 (JP) 2011-50906

(51) Int. Cl. H03K 3/03

(52) U.S. Cl. 331/57

(57) ABSTRACT

According to one embodiment, a voltage control oscillating circuit is provided with a ring oscillator, a control current generating unit and a constant current generating unit. The ring oscillator has an odd number of inverters connected in a ring shape. The control current generating unit converts an input control voltage into a control current and to supply the control current to the ring oscillator as a first supply current. The constant current generating unit generates a constant current and to supply the generated constant current to the ring oscillator as a second supply current which is added to the control current.

### CROSS-REFERENCE TO RELATED APPLICATION(S)

This application is based upon and claims the benefit of priority from the prior Japanese Patent Application No. 2011-50906, filed on Mar. 3, 2011, the entire contents of which are incorporated herein by reference.

### FIELD

Embodiments described herein relate generally to a voltage controlled oscillator circuit.

### BACKGROUND

A voltage controlled oscillator circuit (hereinafter, referred to as “VCO circuit”) is widely used. The VCO circuit controls an oscillation frequency by an input control voltage.

As a VCO circuit, a VCO circuit of a ring-oscillator type is known. The VCO circuit of the ring-oscillator type is provided with a ring oscillator and a voltage/current conversion circuit. The ring oscillator has odd-stage inverters connected in a ring shape. The voltage/current conversion circuit converts an input control voltage into a current, and supplies the converted current to the ring oscillator as a supply current for the ring oscillator.

Such a VCO circuit of the ring-oscillator type needs to be capable of changing the oscillation frequency widely with respect to change of the control voltage, in order to oscillate the VCO circuit at a desired frequency, so that the conversion sensitivity Kv of the VCO circuit becomes large. When the conversion sensitivity Kv is large, a change of the oscillation frequency relative to a change of the control voltage becomes large, which make it difficult to suppress phase noise.

Further, when variation of delay characteristic occurs in inverters composing the ring oscillator due to manufacturing variation or variation of an operating condition of the VCO circuit, the oscillation frequency relative to the control voltage deviates from the desired value.

### BRIEF DESCRIPTION OF THE DRAWINGS

FIG. 1 is a circuit diagram of a VCO circuit according to a first embodiment.

FIG. 2 is a diagram to explain an operation of the VCO circuit according to the first embodiment.

FIG. 3 is a circuit diagram of a VCO circuit according to a second embodiment.

FIG. 4 is a diagram to explain an operation of the VCO circuit according to the second embodiment.

FIG. 5 is circuit diagram of a VCO circuit according to a third embodiment.

FIGS. 6A, 6B show relationships between a control voltage and an oscillation frequency of a VCO circuit, respectively.

FIGS. 7A, 7B show relationships between the control voltage and the oscillation frequency of a VCO circuit, respectively.

FIG. 8 is a circuit diagram of a VCO circuit according to a fourth embodiment.

FIG. 9 is a block diagram showing an example of an oscillation characteristic correcting unit of the VCO circuit according to the fourth embodiment.

FIG. 10 is a flow chart showing an example of processing executed by the oscillation characteristic correcting unit.

FIG. 11 is a diagram to explain processing executed by a switching control unit which is provided in the oscillation characteristic correcting unit.

FIG. 12 is a block diagram showing an example of a phase locked loop.

### DETAILED DESCRIPTION

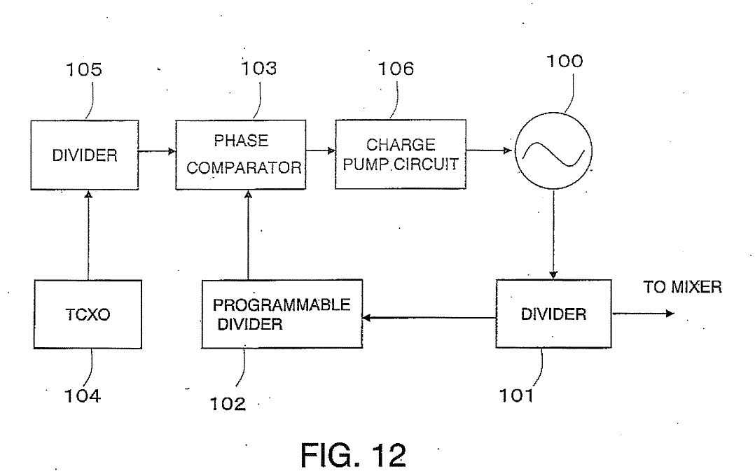

Embodiments described below are adaptable to a phase locked loop shown in FIG. 12. In FIG. 12, an output from a VCO circuit 100 is divided by a divider 101, and the divided output is provided to a mixer, for example. The divided output of the divider 101 is further divided by a programmable divider 102 and is input into a phase comparator 103 as a feedback clock signal. An output which is obtained by dividing an output of a temperature compensation crystal oscillator 104 by a divider 105 is input into the phase comparator 103 as a reference clock signal. The phase comparator 103 compares the feedback clock signal and the divided output as the reference clock signal, and outputs a phase difference. The output phase difference is transmitted to a charge pump circuit 106 which operates as an integrator. The voltage of the VCO circuit 100 is controlled by the output of the charge pump circuit 106.

According to one embodiment, a voltage control oscillating circuit is provided with a ring oscillator, a control current generating unit and a constant current generating unit. The ring oscillator has an odd number of inverters connected in a ring shape. The control current generating unit converts an input control voltage into a control current and to supply the control current to the ring oscillator as a first supply current. The constant current generating unit generates a constant current and to supply the generated constant current to the ring oscillator as a second supply current which is added to the control current.

Hereinafter, further embodiments will be described with reference to the drawings. In the drawings, the same reference numerals denote the same or similar portions respectively.

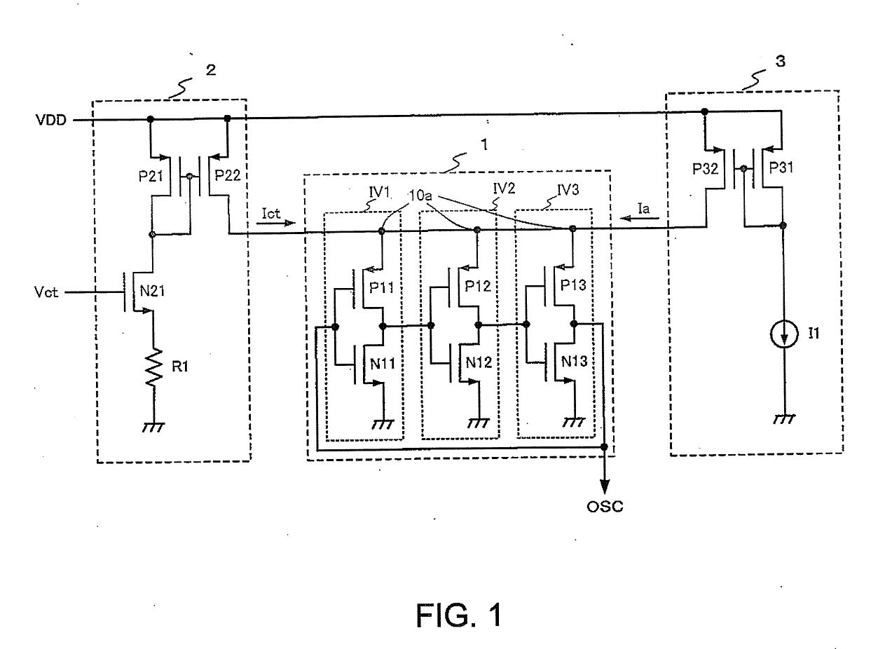

A first embodiment will be described with reference to FIG. 1.

As shown in FIG. 1, a VCO circuit of the first embodiment is provided with a ring oscillator 1, a control current generating unit 2, and a constant current generating unit 3.

The ring oscillator 1 has an odd number of inverters, for example, three inverters IV1, IV2, IV3, which are connected in a ring shape. The control current generating unit 2 converts an input control voltage Vct to a control current Ict, and supplies the control current Ict to a current supply terminal 10a of the ring oscillator 1 as a supply current.

The constant current generating unit 3 generates a constant current Ia, and supplies the constant current Ia to the ring oscillator 1 as a supply current to be added to the control current Ict.

Each of the inverters IV1, IV2, IV3 has a complementary connection of each of P-channel insulated gate field effect transistors (PMOS transistors) P11, P12, P13 and each of N-channel insulated gate field effect transistors (NMOS transistors) N11, N12, N13, which is provided between a power supply terminal VDD and a ground terminal.

The inverters IV1, IV2, IV3 are connected in cascade, respectively. Specifically, an output terminal of the inverter IV1 is connected to an input terminal of the inverter IV2. An output terminal of the inverter IV2 is connected to an input terminal of the inverter IV3. An output terminal of the inverter IV3 is connected to an input terminal of the inverter IV1. An oscillation frequency OSC of the ring oscillator 1 is determined by a total delay time of signal propagation of the inverters IV1, IV2, IV3. Accordingly, the number of inverters composing the ring oscillator 1 is different depending on a desired oscillation frequency.

The control current generating unit 2 has PMOS transistors P21, P22 and an NMOS transistor N21. A source of the PMOS transistor P21 is connected to the power supply terminal VDD. A gate of the PMOS transistor P21 is connected to a drain. A drain of the NMOS transistor N21 is connected to a drain of the PMOS transistor P21. A source of the NMOS transistor N21 is connected to the ground terminal via a resistor R1. The control voltage Vct is applied to a gate of the NMOS transistor N21.

A source of the PMOS transistor P22 is connected to the power supply terminal VDD. A gate of the PMOS transistor P22 is connected to a drain of the PMOS transistor P21. A drain of the PMOS transistor P22 is connected to sources of the PMOS transistors P11, P12, P13.

An on-resistance of the NMOS transistor N21 changes according to a value of the control voltage Vct. A current which flows in the PMOS transistor P21 changes according to the on-resistance of the NMOS transistor N21 and a value of the resistor R1. The PMOS transistor P21 and the PMOS transistor P22 compose a current mirror circuit. Thus, a current corresponding to a current flowing in the PMOS transistor P21 is output from the PMOS transistor P22.

The control current Ict output from the drain of the PMOS transistor P22, as a supply current for the ring oscillator 1, changes according to a value of the control voltage Vct. A voltage/current conversion rate of the control current generating unit 2 changes according to a value of the resistor R1.

The constant current generating unit 3 is provided with PMOS transistors P31, P32. A source of the PMOS transistor P31 is connected to the power supply terminal VDD. A drain of the PMOS transistor P31 is connected to a constant current supply I1. A gate of the PMOS transistor P31 is connected to a drain. A source of the PMOS transistor P32 is connected to the power supply terminal VDD. A gate of the PMOS transistor P32 is connected to a drain of the PMOS transistor P31. A drain of the PMOS transistor P32 is connected to the sources of the PMOS transistors P11, P12, P13 of the ring oscillator 1.

Since the PMOS transistor P31 is connected to the constant current supply I1, a constant current flows in the PMOS transistor P31. The PMOS transistor P32 composes a current mirror circuit together with the PMOS transistor P31. Accordingly, the constant current Ia is output from the drain of the PMOS transistor P32.

As explained above, in the embodiment, the constant current Ia output from the constant current generating unit 3 is supplied to the current supply terminal 10a of the ring oscillator 1, and is added to the control current Ict which is supplied from the control current generating unit 2. Accordingly, in the embodiment, the control current Ict supplied from the control current generating unit 2 can be decreased by an amount of the added constant current Ia.

The voltage/current conversion rate of the control current Ict to the control voltage Vct can be decreased. As a result, a change i.e. a conversion sensitivity Kv of the oscillation frequency becomes small with respect to a change of the control voltage Vct.

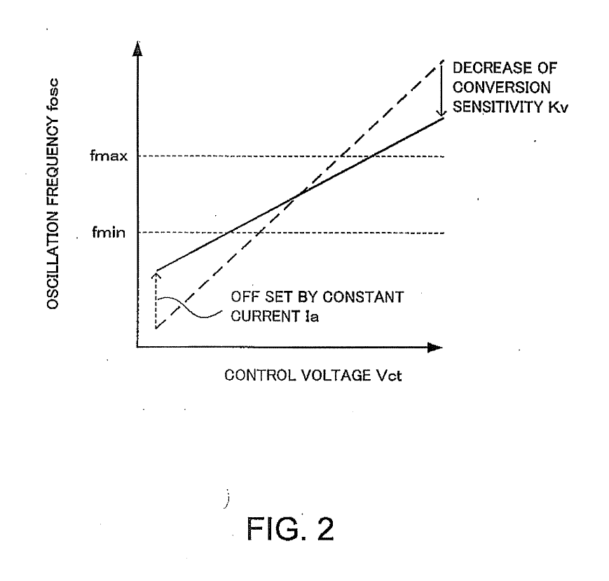

FIG. 2 shows a state of decrease of the conversion sensitivity Kv according to an added constant current Ia.

In FIG. 2, a horizontal axis shows a control voltage Vct, and a vertical axis shows an oscillation frequency fosc of the ring oscillator 1. FIG. 2 shows a state of change of the oscillation frequency fosc relative to a change of the control voltage Vct. The characteristic of a solid line indicates a case where a constant current Ia is added to a control current Ict according to the embodiment. The characteristic of a broken line indicates a case where a constant current Ia is not added to a control current Ict according to a conventional technique. In FIG. 2, fmin and fmax denote a minimum oscillation frequency and a maximum oscillation frequency to be required with respect to the ring oscillator 1, respectively.

As shown by the broken line, when a constant current Ia is not added to a control current Ict, the control voltage Vct for producing the control current Ict needs to be changed drastically in order to change the oscillation frequency from fmin to fmax. Accordingly, the conversion sensitivity Kv needs to be set large.

On the other hand, when a constant current Ia is added by the constant current generating unit 3 as shown by the solid line, the control voltage Vct may be changes gradually in order to change the oscillation frequency from fmin to fmax since an offset exists with respect to the oscillation frequency due to the constant current Ia. The change sensitivity Kv may be set small.

According to the embodiment, a constant current Ia generated by the constant current generating unit 3 is added to a supply current to the ring oscillator 1. As a result, the conversion sensitivity Kv of the ring oscillator 1 can be decreased so that the VCO circuit of the embodiment can decrease phase noise.

When the VCO circuit of the embodiment is formed by a semiconductor integrated circuit, the oscillation frequency of the ring oscillator may deviate from a designed specification due to a manufacturing variation etc. In a second embodiment described below, the deviation of the oscillation frequency can be corrected.

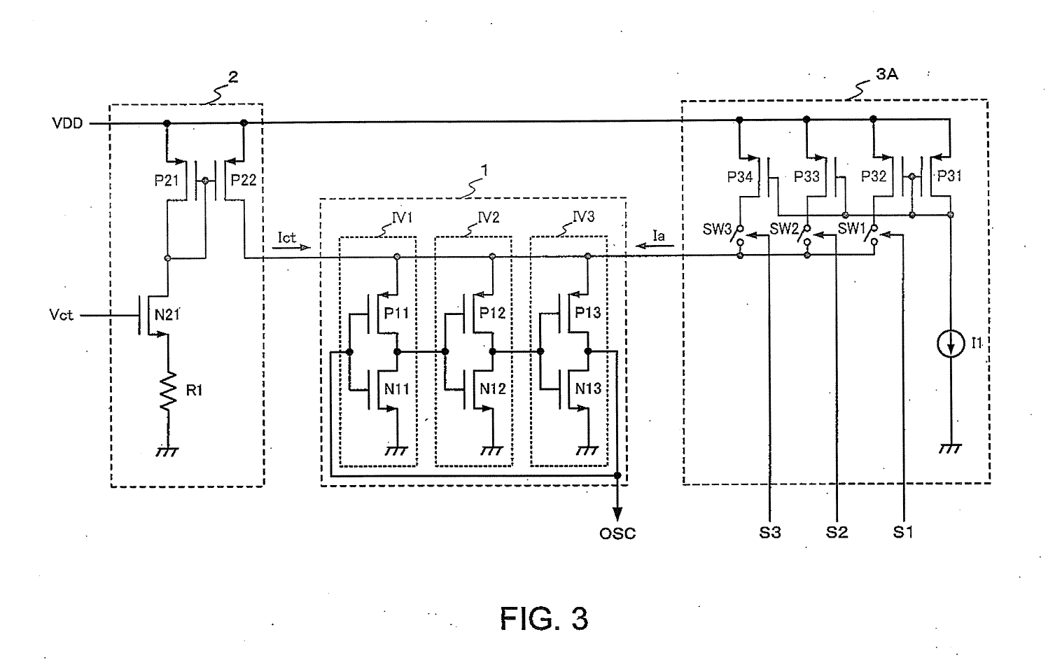

FIG. 3 is a circuit diagram of a VCO circuit according to the second embodiment.

The second embodiment is different from the first embodiment described above in that a constant current generating unit 3A is provided in place of the constant current generating unit 3. Values of a constant current Ia output from the constant current generating unit 3A is switched by control signals S1 to S3.

The constant current generating unit 3A has PMOS transistors P31, P32 which compose a current mirror circuit, similarly to the constant current generating unit 3 of the first embodiment. Sources of the PMOS transistors P31, P32 are connected to a power supply terminal VDD. A drain of the PMOS transistor P31 is connected to a constant current supply I1.

In the embodiment, PMOS transistors P33, P34 are connected in parallel to the PMOS transistor P32. Gates of the PMOS transistors P33, P34 are connected to the drain of the PMOS transistor P31. The PMOS transistors P33, P34 compose a current mirror circuit together with the PMOS transistor P31, and constant currents are output from the respective drains of the PMOS transistors P33, P34.

Each drain of the PMOS transistors P32, P33, P34 are connected to sources of PMOS transistors P11, P12, P13 of a ring oscillator 1 via each of switches SW1, SW2, SW3 as switching units.

Turning ON and OFF of the switches SW1, SW2, SW3 are controlled by control signals S1, S2, S3, respectively. Accordingly, values of a constant current Ia which is supplied to the ring oscillator 1 can be switched by the control signals S1, S2, S3 stepwise.

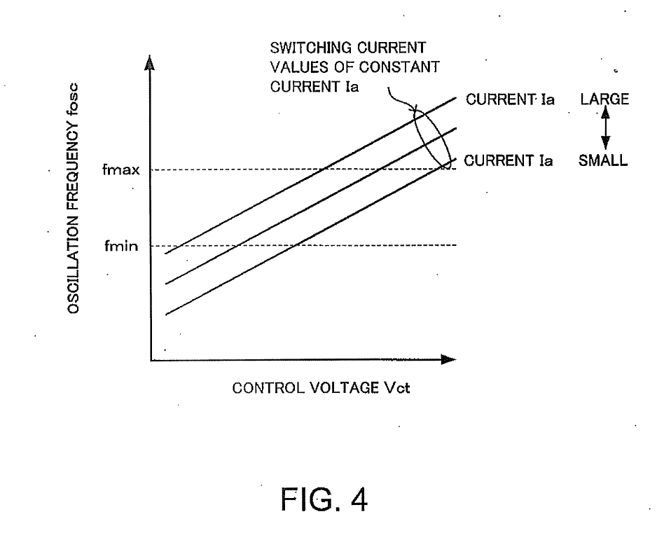

FIG. 4 shows an oscillation characteristic of the VCO circuit according to the second embodiment, using the value of the constant current Ia as a parameter. The offset of frequency of the VCO circuit is changed by switching values of the constant current Ia. Accordingly, the value of the oscillation frequency fosc relative to the control voltage Vct shifts upward and downward. As a result, even when the oscillation frequency fosc relative to the control voltage Vct deviates from a desired value due to a manufacturing variation of the VCO circuit etc., the oscillation frequency fosc can be set near to the desired value by switching the values of the constant current Ia.

According to the embodiment, values of the constant current Ia which is supplied to the ring oscillator 1 is switched, so that deviation of the oscillation frequency fosc value relative to the control voltage Vct can be corrected.

When the oscillation frequency deviates due to a manufacturing variation etc., the conversion sensitivity Kv also tends to deviate following the deviation of the oscillation frequency. For example, when the oscillation frequency deviates upward, the conversion sensitivity Kv also tends to increase. When the oscillation frequency deviates downward, the conversion sensitivity Kv also tends to decrease. In a third embodiment described below, the conversion sensitivity Kv can be corrected as well as the deviation of the oscillation frequency.

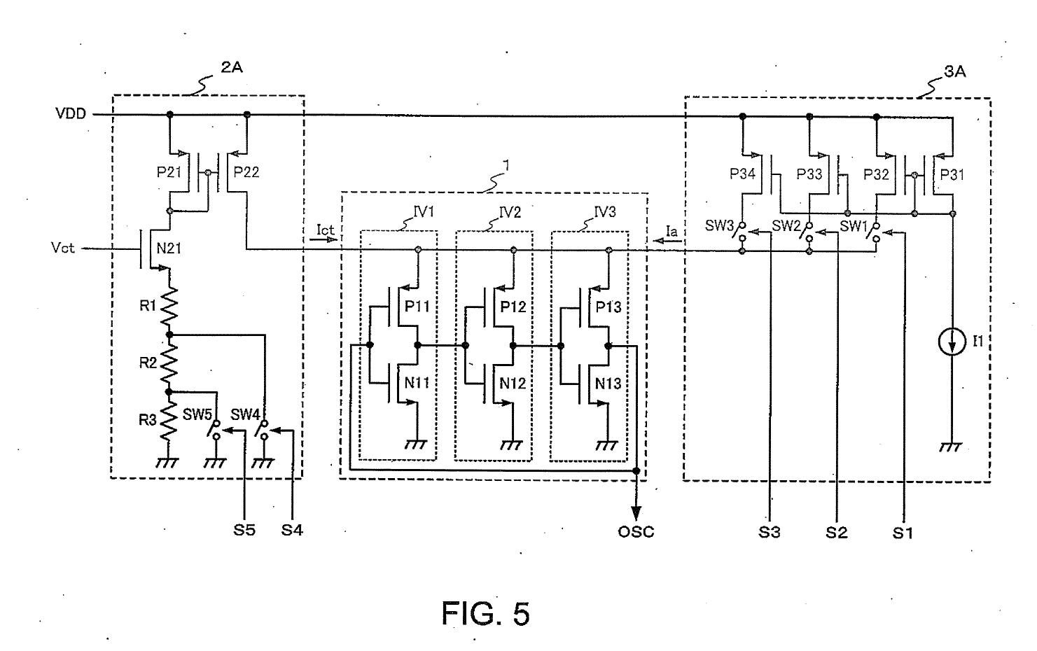

FIG. 5 is a circuit diagram of a VCO circuit according to the third embodiment.

The third embodiment is different from the second embodiment in that a control current generating unit 2A is used in place of the control current generating unit 2. Values of a control current Ict which is output from the control current generating unit 2A is switched by control signals S4, S5.

Specifically, the control current generating unit 2A is provide with PMOS transistors P21, P22, an NMOS transistor N21, and a resistor R1, similarly to the control current generating unit 22 of the second embodiment. In the third embodiment, resistors R2, R3 are inserted in series between the resistor R1 and a ground terminal. Further, a switch SW4 is connected between a connection point of the resistors R1, R2 and the ground terminal. A switch SW5 is connected between a connection point of the resistors R2, R3 and the ground terminal. The switches SW4, SW5 compose separate switching units, respectively. Turning ON and OFF of the switches SW4, SW5 are controlled by control signals S4, S5, respectively.

By switching combinations of turning ON and OFF of the switches SW4, SW5, the resistance value of the total of the resistors R1 to R3 which are connected between a source of the NMOS transistor N21 and the ground terminal electrically changes. Thus, even when the value of a control voltage Vct is unchanged, a current flowing in the NMOS transistor N21 can be changed. The total of the resistors R1 to R3 will be expressed as “resistor R”. The resistance values of the resistors R1 to R3 and R will be expressed as “R1”, “R2” and “R3”, respectively

When the switch SW4 is set ON and the switch SW5 is set OFF, the resistance value of the resistor R becomes “R1”. When the switch SW4 is set OFF and the switch SW5 is set ON, the resistance value of the resistor R becomes “R1+R2”. When the switch SW4 is set OFF and the switch SW5 is set OFF, the resistance value of the resistor R becomes “R1+R2+R3”. In such a manner, the resistance value of the resistor R may be increased sequentially, and the current flowing in the NMOS transistor N21 may be decreased sequentially.

When the current flowing in the NMOS transistor N21 changes, a control current Ict which is output from a drain of the PMOS transistor P22 also changes. Thus, the voltage/current conversion rate of the control current Ict changes with respect to the control voltage Vct. This means that the conversion sensitivity Kv changes with respect to the control voltage Vct.

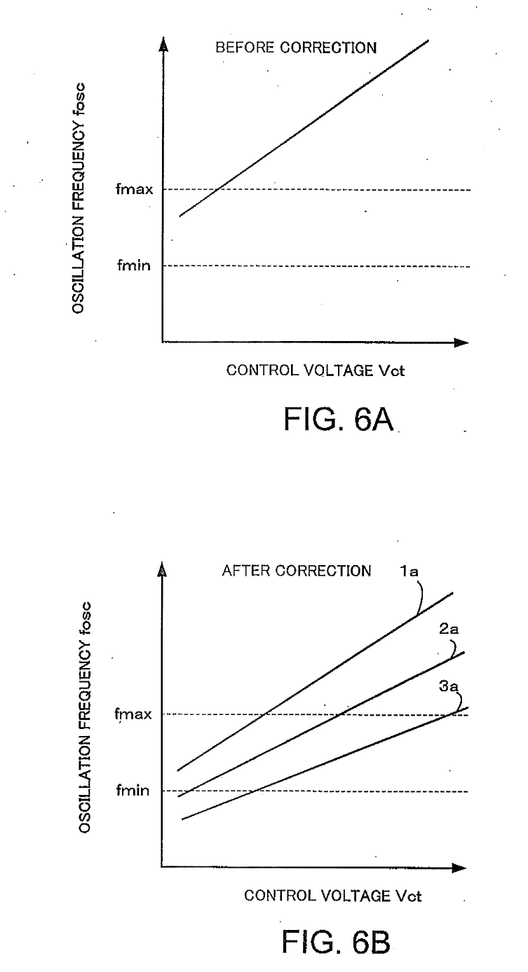

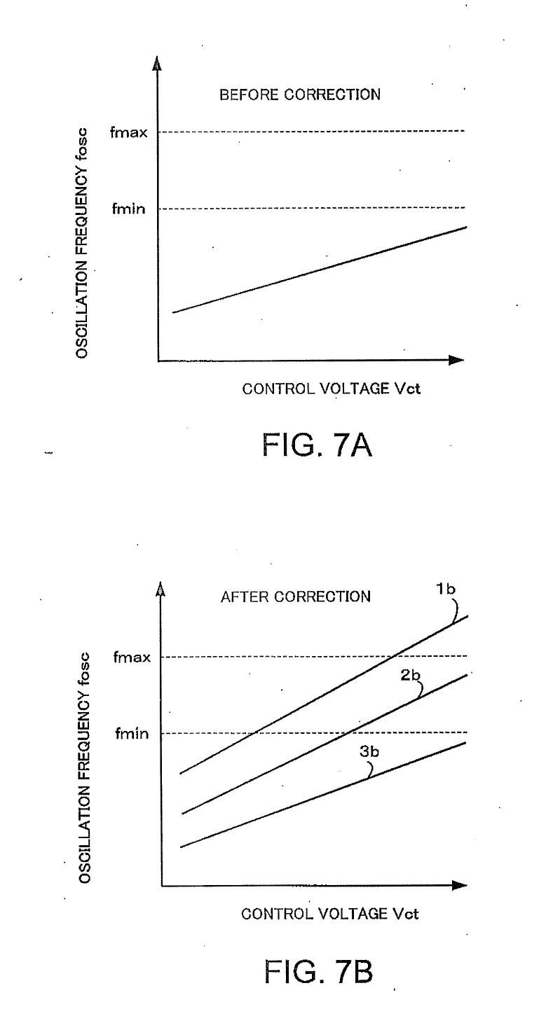

FIGS. 6A, 6B and FIGS. 7A, 7B are graphs which show relationships between a control voltage and an oscillation frequency of a VCO circuit, respectively.

FIG. 6A indicates an oscillation characteristic before correcting the oscillation frequency and the conversion sensitivity. Further, FIG. 6A shows an example where the value of the oscillation frequency fosc deviates upward relative to the control voltage Vct and the conversion sensitivity Kv deviates upward.

On the other hand, FIG. 6B shows an example where the oscillation frequency and the conversion sensitivity are corrected according to the third embodiment. Specifically, FIG. 6B shows an example where switching of values of a constant current Ia and switching of values of the control current Ict are combined to correct the oscillation frequency and the conversion sensitivity as shown by lines 1a to 3a. The switching of the values of the constant current Ia is performed by a constant current generating unit 3A. The switching of the values of the control current Ict is performed by the control current generating unit 2A. The correction according to the line 3a satisfies a specification requiring a maximum frequency fmax and a minimum frequency fmin, and can be selected as an optimum correction.

Contrary to FIG. 6A, FIG. 7A shows an example of an oscillation characteristic before correction where the value of the oscillation frequency fosc deviates downward with respect to the control voltage Vct and the conversion sensitivity Kv deviates downward.

FIG. 7B shows an example where the oscillation frequency and the conversion sensitivity are corrected as shown by the lines 1b to 3b. The correction according to the line 1b satisfies a specification requiring a maximum frequency fmax and a minimum frequency fmin, and can be selected as optimum correction.

According to the third embodiment, the deviation of the oscillation frequency fosc due to switching of the values of the constant current Ia can be corrected. In addition to the correction, voltage/current conversion rates of the control current Ict relative to the control voltage Vct are switched to correct the deviation of the conversion sensitivity Kv relative to the control voltage Vct.

During operation of the VCO circuit, the oscillation frequency fosc and the conversion sensitivity Kv relative to the control voltage Vct may deviate from a range of a primary specification, due to variation of a supply voltage and variation of an ambient temperature.

In a fourth embodiment described below, these oscillation characteristics relative to the control voltage Vct can be automatically corrected during operation.

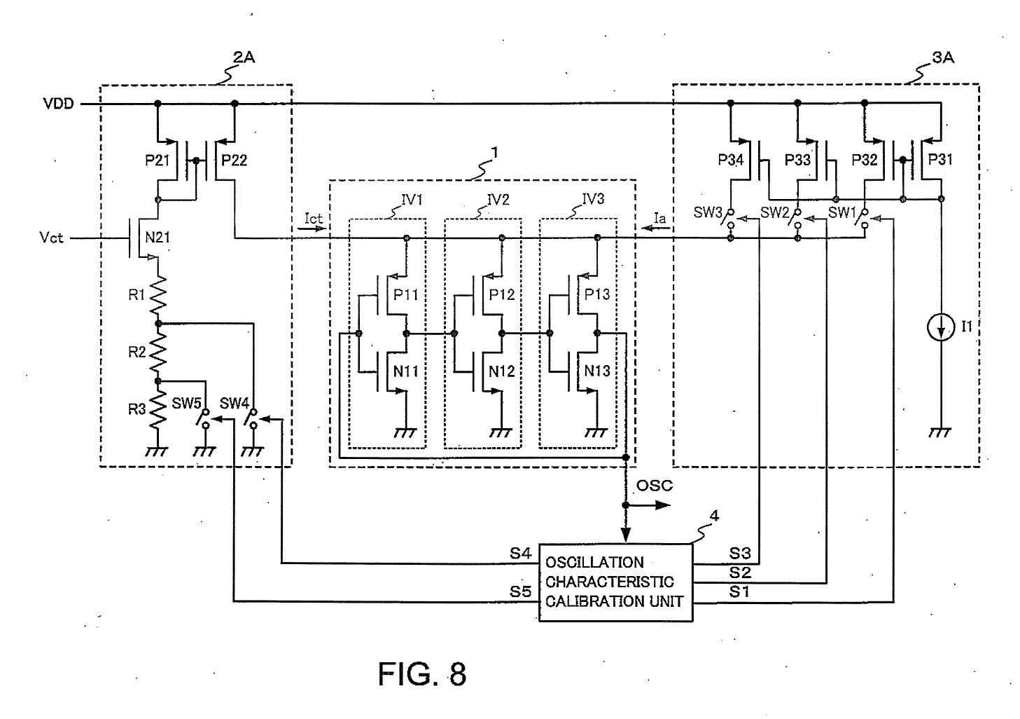

FIG. 8 is a circuit diagram of a VCO circuit according to the fourth embodiment.

The VCO circuit of the fourth embodiment is provided with an oscillation characteristic correcting unit 4 in addition to the configuration of the third embodiment in FIG. 5. In the fourth embodiment, a correction mode is provided to correct oscillation characteristic of a ring oscillator 1. The oscillation characteristic correcting unit 4 *corrects the oscillation characteristic of the ring oscillator 1 by using a correction control voltage which is input during the correction mode.

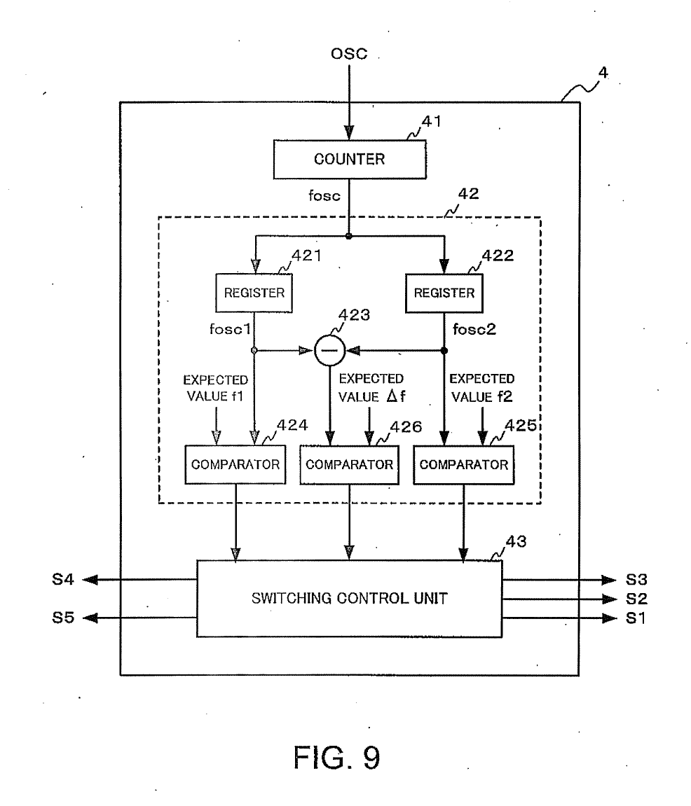

FIG. 9 is a block diagram showing a detailed example of the oscillation characteristic correcting unit 4.

The oscillation characteristic correcting unit 4 is provided with a counter 41, a comparison unit 42, and a switching control unit 43. The counter 41 counts a frequency of an output OSC of the ring oscillator 1 shown in FIG. 8. The comparison unit 42 compares count values fosc1, fosc2 of the counter 41 and the difference value “fosc2−fosc1” with expected values, respectively. The count values fosc1, fosc2 are obtained when first and second correction control voltages Vct1, Vct2 set as Vct1<Vct2 in advance are input into the control current generating unit 2A.

The switching control unit 43 controls to set control signals S1 to S3 to be transmitted to a constant current generating unit 3A and to set control signals S4, S5 to be transmitted to a control current generating unit 2A, based on the results of the comparison performed by the comparison unit 42.

The comparison unit 42 is provided with registers 421, 422, a subtracter 423 and comparators 424 to 426. The comparator 424 stores the count value fosc1 of the counter 41 obtained when the first correction control voltage Vct1 is input. The register 422 stores the count value fosc2 of the counter 41 obtained when the second correction control voltage Vct2 is input. The subtracter 423 calculates the difference value “fosc2−fosc1” from the count values stored in the registers 421, 422. The comparator 424 compares the count value fosc1 stored in the register 421 with an expected value f1. The comparator 425 compares the count value fosc2 stored in the register 422 with an expected value f2. The comparator 426 compares the difference value “fosc2−fosc1” calculated by the subtracter 423 with an expected value Δf.

The expected value Δf of the difference value is obtained by Δf=f2−f1, and is an expected value relative to the conversion sensitivity Kv of the VCO circuit. When the difference value “fosc2−fosc1” is larger than the expected value Δf, it indicates that the conversion sensitivity Kv is larger than a specification. When the difference value “fosc2−fosc1” is smaller than the expected value Δf, it indicates that the conversion sensitivity Kv is smaller than the specification.

The switching control unit 43 controls to set the control signals S1 to S3 to be transmitted to the constant current generating unit 3A and the control signals S4, S5 to be transmitted to the control current generating unit 2A, based on outputs of the comparators 424 to 426, as described below.

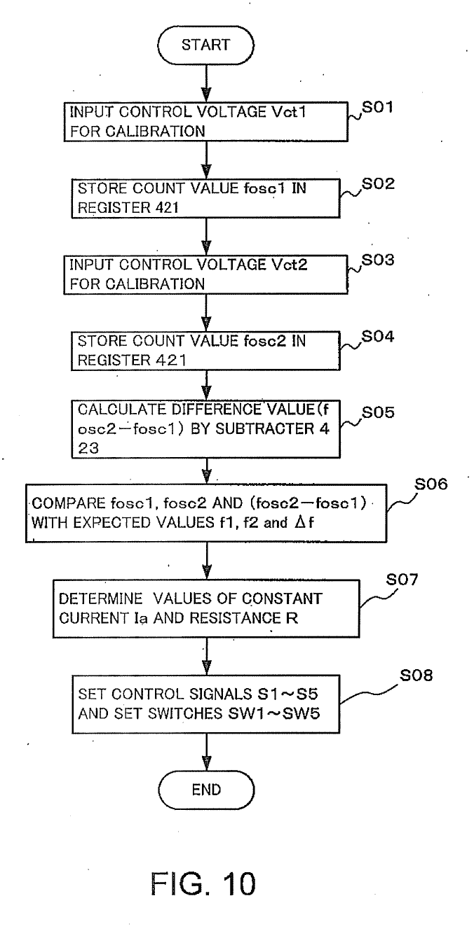

FIG. 10 is a flowchart showing processing of the oscillation characteristic correcting unit 4.

After a correction mode is started, a first correction control voltage Vct1 set in advance is input to a gate of the NMOS transistor N21 shown in FIG. 8 (Step S01). The counter 41 counts the frequency of the output OSC of the ring oscillator 1, and stores the counted value fosc1 in the register 421 (Step S02).

Then, a second correction control voltage Vct2 set in advance is input to the gate of the NMOS transistor N21 shown in FIG. 8 (Step S03). The counter 41 counts the frequency of the output OSC of the ring oscillator 1, and stores the counted value fosc2 in the register 422 (Step S04).

The subtracter 423 calculates the difference value “fosc2−fosc1” from the count values stored in the registers 421, 422 (Step S05).

The comparators 424, 425, 426 compare the count values fosc1, fosc2 and the difference value “fosc2−fosc1” with the expected values f1, f2, and Δf, respectively (Step S06).

Based on the results of the comparison performed by the comparators 424, 425, 426, the switching control unit 43 determines the value of the constant current Ia to be output from the constant current generating unit 3A shown in FIG. 8, and determines the resistance value of the total resistor R including the resistors R1 to R3 which are connected in series to the source of the NMOS transistor N21 of the control current generating unit 2A (Step S07).

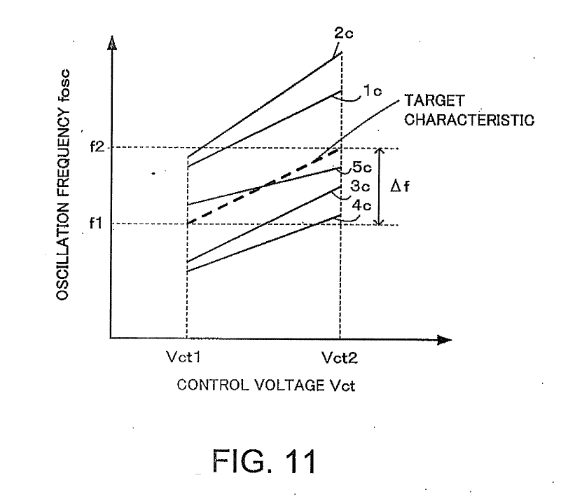

A processing of the switching control unit 43 will be explained with reference to FIG. 11. FIG. 11 exemplifies five oscillation characteristics 1c to 5c with respect to the correction control voltages Vct1, Vct2 (Vct1<Vct2).

The oscillation characteristic 1c is an example of a case where fosc1>f1, fosc2>f2, and (fosc2−fosc1)≈Δf. In this case, the conversion sensitivity Kv is substantially as per a specification and the oscillation frequency deviates upward. The switching control unit 43 lowers the value of the constant current Ia from a value set currently, and sets the control signals S1 to S3, S4 and S5 so that the resistor R may maintain a value set currently.

The oscillation characteristic 2c is an example of a case where fosc1>f1, fosc2>f2, and (fosc2−fosc1)>Δf. In this case, the conversion sensitivity Kv deviates upward. Accordingly, the switching control unit 43 lowers the constant current Ia from a value set currently, and sets the control signals S1 to S3, S4 and S5 so that the resistor R may have a higher value than a value set currently.

The oscillation characteristic 3c is an example of a case where fosc1<f1, fosc2<f2, and (fosc2−fosc1)≈Δf. In this case, the switching control unit 43 increases the constant current Ia from a value set currently, and sets the control signals S1 to S3, S4, S5 so that the resistor R may maintain a value set currently.

The oscillation characteristic 4c is an example of a case where fosc1<f1, fosc2<f2, and (fosc2−fosc1)<Δf. In this case, the switching control unit 43 increases the constant current Ia from a value set currently, and sets the control signals S1 to S3, S4 and S5 so that the resistor R may have a lower value than a value set currently.

The oscillation characteristic 5c is an example of a case where fosc1>f1, fosc2>f2, and (fosc2−fosc1)<Δf. In this case, the oscillation characteristic becomes near to a target characteristic by only increasing the conversion sensitivity Kv. Accordingly, the switching control unit 43 maintain the constant current Ia at a value set currently, and sets the control signals S1 to S3, S4 and S5 so that the resistor R may have a lower value than a value set currently.

The switching control unit 43 transmits the control signals S1 to S5 to the switches SW1 to SW5, and sets turning ON and OFF of the switches SW1 to SW5 (Step S08). By the setting, a series of the correction processing ends.

According to the fourth embodiment, during the operation of the VCO circuit, the oscillation characteristic correcting unit 4 can correct the oscillation characteristic. Accordingly, even when the oscillation characteristic deviates due to variation of a supply voltage and variation of an ambient temperature, the deviation can be automatically corrected.

According to the VCO circuits of the fourth embodiments, phase noise and deviation of the oscillation frequency can be decreased.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A voltage control oscillating circuit comprising:
a ring oscillator having an odd number of inverters connected in a ring shape;
a control current generating unit to convert an input control voltage into a control current and to supply the control current to the ring oscillator as a first supply current; and
a constant current generating unit to generate a constant current and to supply the generated constant current to the ring oscillator as a second supply current which is added to the control current.

2. The circuit according to claim 1, wherein the ring oscillator has a current supply terminal and a ground terminal, the constant current generating unit is provided with first and second MOS transistors, sources of the first and second MOS transistors are connected to a voltage supply, gates of the first and second MOS transistors are connected to each other, a drain of the first MOS transistor is connected to a current supply, a drain of the first MOS transistor is connected to the gate of the first MOS transistor, and a drain of the second MOS transistor is connected to the current supply terminal.

3. The circuit according to claim 1, wherein the constant current generating unit further includes a first switching unit to switch the current value of the constant current which is output to the ring oscillator.

4. The circuit according to claim 3, wherein the ring oscillator has a current supply terminal and a ground terminal, and the constant current generating unit has first and second MOS transistors and a first switching unit provided with at least one third MOS transistor and at least one first switch, and wherein
sources of the first and second MOS transistors are connected to a voltage supply, gates of the first and second MOS transistors are connected to each other, a drain of the first MOS transistor is connected to a current supply, the drain of the first MOS transistor is connected to the gate of the first MOS transistor, and a drain of the second MOS transistor is connected to the current supply terminal, and
a source of at least one of the third MOS transistors is connected to the voltage supply, and a gate of the third MOS transistor is connected to the drain of the first MOS transistor, and the at least one of the first switches controls supply of a current flowing from a drain of the third MOS transistor to the current supply terminal.

5. The circuit according to claim 2, wherein
the control current generating unit is provided with fourth to sixth MOS transistors and a first resistor, sources of the fourth and fifth MOS transistors are connected to the voltage supply, gates of the fourth and fifth MOS transistors are connected to each other, gates of the fourth and fifth MOS transistors are connected to each other, a drain of the fourth MOS transistor is connected to the gate of the fifth MOS transistor and a drain of the sixth MOS transistor, a source of the sixth MOS transistor is grounded via the first resistor, and the control voltage is input to a gate of the sixth MOS transistor.

6. The circuit according to claim 3, wherein the control current generating unit further includes a second switching unit to switch the current value of the control current with respect to the control voltage.

7. The circuit according to claim 6, wherein the ring oscillator has a current supply terminal and a ground terminal, the control current generating unit is provide with fourth to sixth MOS transistors and a first resistor, and the second switching unit has at least two second resistors and at least one second switch, and wherein
sources of the fourth and fifth MOS transistors are connected to the voltage supply, gates of the fourth and fifth MOS transistors are connected to each other, a drain of the fourth MOS transistor is connected to the gate of the fifth MOS transistor and a drain of the sixth MOS transistor, a source of the sixth MOS transistor is grounded via the first resistor, and a control voltage is input to a gate of the sixth MOS transistor, the second resistors is connected in series, and the second switch is connected to the series connected end.

8. The circuit according to claim 6, further comprising an oscillation characteristic correcting unit to control the first and second switching units, and to correct an oscillation characteristic with respect to the control voltage.

9. The circuit according to claim 8, wherein the oscillation characteristic correcting unit includes:
a counter to count an oscillation frequency of the ring oscillator;
a comparison unit to compare count values of the counter and a difference value between the count values with expected values respectively, the count values being obtained when two control voltages of different values are respectively input into the control current generating unit; and
a switching control unit to control switching the first and second switching units based on the result of comparison by the comparison unit.

10. The circuit according to claim 7, further comprising an oscillation characteristic correcting unit to correct an oscillation characteristic with respect to the control voltage, wherein the oscillation characteristic correcting unit includes:
a counter to count an oscillation frequency of the ring oscillator;
a comparison unit to compare count values of the counter and a difference value between the count values with expected values respectively, the count values being obtained when two control voltages of different values are respectively input into the control current generating unit; and
a switching control unit to control switching the first and second switching units based on the result of comparison by the comparison unit.

11. The circuit according to claim 2, wherein the ring oscillator has an odd number of CMOS inverters, and two ends of each of the CMOS inverters is connected to the current supply terminal and the ground terminal respectively.

12. The circuit according to claim 4, wherein the ring oscillator has an odd number of CMOS inverters, and two ends of each of the CMOS inverters is connected to the current supply terminal and the ground terminal respectively.

13. The circuit according to claim 5, wherein the ring oscillator has an odd number of CMOS inverters, and two ends of each of the CMOS inverters is connected to the current supply terminal and the ground terminal respectively.

14. The circuit according to claim 7, wherein the ring oscillator has an odd number of CMOS inverters, and two ends of each of the CMOS inverters is connected to the current supply terminal and the ground terminal respectively.

15. The circuit according to claim 9, wherein the ring oscillator has an odd number of CMOS inverters, and two ends of each of the CMOS inverters is connected to the current supply terminal and the ground terminal respectively.

16. The circuit according to claim 10, wherein the ring oscillator has an odd number of CMOS inverters, and two ends of each of the CMOS inverters is connected to the current supply terminal and the ground terminal respectively.
